(19) United States
(12) Patent Application Publication
(10) Pub. No.: US 2018/0108861 A1
(43) Pub. Date: Apr. 19, 2018

(54) DISPLAY UNIT AND ELECTRONIC APPARATUS

(71) Applicant: JOLED INC., Tokyo (JP)

(72) Inventor: Tomoatsu KINOSHITA, Tokyo (JP)

(21) Appl. No.: 15/724,237

(22) Filed: Oct. 3, 2017

(30) Foreign Application Priority Data
Oct. 17, 2016 (JP) 2016-203303

(51) Int. Cl. H01L 51/52; H01L 27/32; H01L 51/00

(52) U.S. Cl. CPC H01L 51/5225; H01L 51/5234; H01L 51/0097; H01L 27/3244

(57) ABSTRACT

A display unit includes a substrate, a first electrode, a second electrode, and an organic layer. The substrate is provided with a display region that includes a plurality of pixels. The substrate has a curved part and a planar part in the display region. The first electrode is provided over the substrate in the display region. The second electrode faces the first electrode and is provided in common for the plurality of pixels. The second electrode has one or more openings at a location that faces the curved part. The organic layer is provided between the first electrode and the second electrode.

### CROSS REFERENCE TO RELATED APPLICATIONS

This application claims the benefit of Japanese Priority Patent Application JP 2016-203303 filed on Oct. 17, 2016, the entire contents of which are incorporated herein by reference.

### BACKGROUND

The technology relates to a bendable display unit and an electronic apparatus.

A bendable display unit having a curved part has been proposed. For example, reference is made to US Patent Application Publication No. 2014/0300529. In such a display unit, for example, a flexible substrate is used, and bending of this flexible substrate forms a curved part.

### SUMMARY

It is desirable that load to be applied to a curved part be reduced in a bendable display unit.

It is desirable to provide a display unit in which load to be applied to a curved part is reduced, and an electronic apparatus.

A display unit according to an embodiment of the technology includes a substrate, a first electrode, a second electrode, and an organic layer. The substrate is provided with a display region that includes a plurality of pixels. The substrate has a curved part and a planar part in the display region. The first electrode is provided over the substrate in the display region. The second electrode faces the first electrode and is provided in common for the plurality of pixels. The second electrode has one or more openings at a location that faces the curved part. The organic layer is provided between the first electrode and the second electrode.

An electronic apparatus according to an embodiment of the technology is provided with a display unit. The display unit includes a substrate, a first electrode, a second electrode, and an organic layer. The substrate is provided with a display region that includes a plurality of pixels. The substrate has a curved part and a planar part in the display region. The first electrode is provided over the substrate in the display region. The second electrode faces the first electrode and is provided in common for the plurality of pixels. The second electrode has one or more openings at a location that faces the curved part. The organic layer is provided between the first electrode and the second electrode.

### BRIEF DESCRIPTION OF THE DRAWINGS

The accompanying drawings are included to provide a further understanding of the disclosure, and are incorporated in and constitute a part of this specification. The drawings illustrate example embodiments and, together with the specification, serve to explain the principles of the technology.

FIG. 1A is a perspective view of a display unit according to an embodiment of the technology in a folded state.

FIG. 1B is a perspective view of the display unit illustrated in FIG. 1A in an opened state.

FIG. 2 is a side view of the display unit illustrated in FIG. 1B.

FIG. 3 is a cross-sectional view of a configuration of a display region illustrated in FIG. 1B.

FIG. 4 is a plan view of a configuration of a second electrode illustrated in FIG. 3.

FIG. 5 is a plan view of another example (1) of the second electrode illustrated in FIG. 4.

FIG. 6 is a plan view of another example (2) of the second electrode illustrated in FIG. 4.

FIG. 7 is a plan view of another example (3) of the second electrode illustrated in FIG. 4.

FIG. 8 is a plan view of another example (4) of the second electrode illustrated in FIG. 4.

FIG. 9 is a plan view of a configuration of a second electrode according to a comparative example.

FIG. 10 is a block diagram illustrating a functional configuration of the display unit.

FIG. 11 is a block diagram illustrating a configuration of an electronic apparatus.

### DETAILED DESCRIPTION

Some example embodiments of the technology are described below in detail with reference to the accompanying drawings. It is to be noted that the description is given in the following order.

1. Example Embodiment (An example of a display unit in which a second electrode in a curved part is provided with openings)

2. A functional configuration example of a display unit

3. An example of an electronic apparatus

### Example Embodiment

### [Configuration]

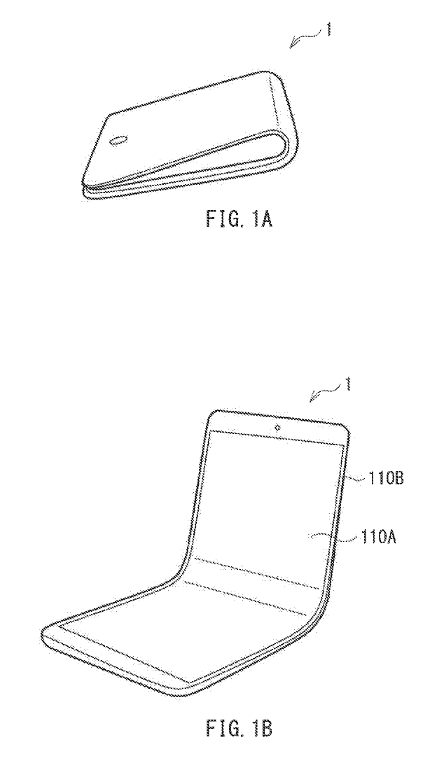

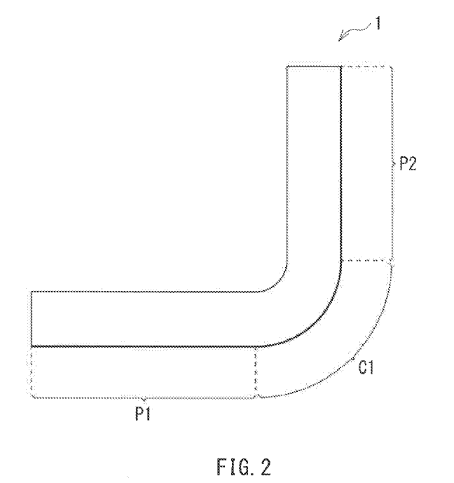

Each of FIGS. 1A and 1B is a perspective view of a configuration of a display unit according to an embodiment of the technology, i.e., a display unit 1. FIG. 2 illustrates a configuration of a side surface of the display unit 1. The display unit 1 may be a bendable display unit, and may include planar parts P1 and P2 and a curved part C1. The curved part C1 is a part that may have a curvature radius of 200 mm or smaller, for example. FIG. 1A illustrates the display unit 1 in a folded state. FIGS. 1B and 2 each illustrate the display unit 1 in an opened state. The display unit 1 in the folded state has a larger curvature radius of the curved part C1 than that of the display unit 1 in the opened state. The display unit 1 may have a rectangular display region 110A in a central part of the display unit 1 and a peripheral region 110B provided around the display region 110A. The display region 110A includes a plurality of pixels in matrix, for example. The peripheral region 110B may include a terminal section that supplies a potential to each of the pixels. For example, the planar part P1, the curved part C1, and the planar part P2 may be provided in this order inside the display region 110A along a long side of the display region 110A.

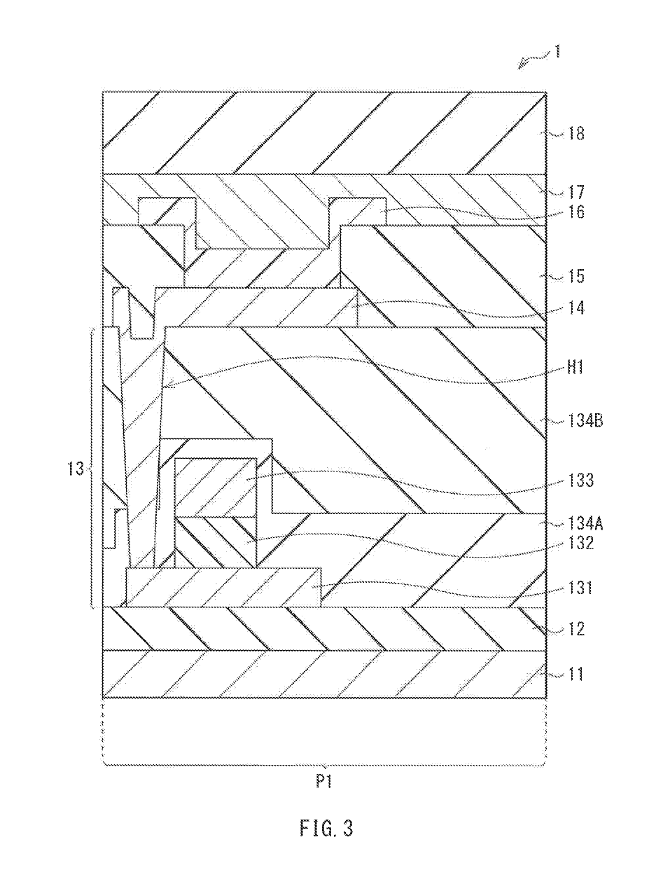

FIG. 3 illustrates a cross-sectional configuration of the display region 110A of the display unit 1. The display unit 1 may include, on a substrate 11, a barrier film 12, a thin-film transistor (TFT) layer 13, a first electrode 14, an insulating film 15, an organic layer 16, a second electrode 17, and a protective layer 18, in this order. The display unit 1 may be a top emission organic electroluminescence (EL) display unit in which light generated in the organic layer 16 is extracted from side of the second electrode 17.

The substrate 11 may be, for example, a flexible substrate, i.e., a substrate having flexibility. The substrate 11 may be made of a resin material such as polyethylene terephthalate (PET), polyimide (PI), polycarbonate (PC), and polyethylene naphthalate (PEN), for example. Alternatively, the substrate 11 may be made of a resin material such as polyamide and polyethersulfone (PES), for example. The material that forms the substrate 11 is not limited to the resin material; a metal film such as stainless steel (SUS) with an insulating material being formed thereon may be used. Providing the substrate 11 with the planar parts P1 and P2 and the curved part C1 allows the display unit 1 to be bendable.

The barrier film 12 may be in contact with the substrate 11, and may be provided on an entire front surface of the substrate 11. The barrier film 12 may be provided to prevent movement of a substance that can be a contamination source from the substrate 11 to the TFT layer, for example. Non-limiting examples of the substance that can be a contamination source may include moisture and sodium (Na). The barrier film 12 may be, for example, spin-on-glass (SOG), and may be made of a silica-based polymer compound.

The TFT layer 13 on the barrier film 12 may include a semiconductor layer 131, a gate insulating film 132, a gate electrode 133, and interlayer insulating films 134A and 134B, in order from a position close to the barrier film 12. The first electrode (i.e., source-drain electrode) 14 may be electrically coupled to the semiconductor layer 131. In other words, the TFT layer 13 may include a top gate thin-film transistor, for example.

The semiconductor layer 131 may be provided at a selective region on the barrier film 12. The semiconductor layer 131 may include a channel region (active layer) in a region that faces the gate electrode 133. The semiconductor layer 131 may be configured by an oxide semiconductor that contains, as a main component, one or more elements of indium (In), gallium (Ga), zinc (Zn), tin (Sn), titanium (Ti), and niobium (Nb), for example. Specific but non-limiting examples of the oxide semiconductor may include indium-tin-zinc oxide (ITZO), indium-gallium-zinc oxide (IGZO: InGaZnO), zinc oxide (ZnO), indium-zinc oxide (IZO), indium-gallium oxide (IGO), indium-tin oxide (ITO), and indium oxide (InO). Alternatively, the semiconductor layer 131 may be made of a material such as low-temperature polycrystalline silicon (LTPS) and amorphous silicon (a-Si).

The gate insulating film 132 may be a single-layer film that is made of one of materials such as silicon oxide (SiOₓ), silicon nitride (SiNₓ), silicon oxynitride (SiON), and aluminum oxide (AlOₓ), for example. Alternatively, the gate insulating film 132 may be a multi-layered film that includes two or more of the above-described materials, for example.

The gate electrode 133 may control a carrier density inside the semiconductor layer 131 by means of a gate voltage (Vg) that is applied to the gate electrode 133. The gate electrode 133 may also serve as a wiring line that supplies a potential. The gate electrode 133 may be made of a simple substance that contains one of materials such as titanium (Ti), tungsten (W), tantalum (Ta), aluminum (Al), molybdenum (Mo), silver (Ag), neodymium (Nd), and copper (Cu), for example. Alternatively, the gate electrode 133 may be made of an alloy that includes one of the above-described materials, for example. The gate electrode 133 may be made of a compound that contains one or more of the above-described materials, or configured by a multi-layered film that contains two or more of the above-described materials, for example. The gate electrode 133 may be configured by a transparent electrically-conductive film made of a material such as ITO, for example.

The gate electrode 133, the gate insulating film 132, the semiconductor layer 131, and the barrier film 12 may be covered with the interlayer insulating film 134A, and the interlayer insulating film 134A is covered with the interlayer insulating film 134B. The interlayer insulating films 134A and 134B may be each made of an organic material such as an acrylic-based resin, polyimide (PI), and a novolac-based resin, for example. Alternatively, the interlayer insulating film 134A may be made of an inorganic material such as silicon oxide, silicon nitride, silicon oxynitride, and aluminum oxide, for example.

The first electrode 14 may include, for example, a metal or a transparent electrically-conductive film similar to any of the above-described materials listed as the material that forms the gate electrode 133. It is desirable, without limitation, that the first electrode 14 serve as the source-drain electrode and as an anode electrode, and be made of a material having favorable electric conductivity.

The first electrode 14 may be provided at a selective region on the interlayer insulating film 134B for each pixel, for example. The first electrode 14 may also serve as an electrode, i.e., the anode electrode that injects holes into a light-emitting layer described later of the organic layer 16, for example. The first electrode 14 may be made of an electrically-conductive material having light reflectivity. For example, the first electrode 14 may be made of a simple substance of a metal element such as silver (Ag) and aluminum (Al), or an alloy thereof. The first electrode 14 may be electrically coupled to the semiconductor layer 131 through a connection hole H1 provided in the interlayer insulating films 134A and 134B.

The insulating film 15 may be provided between the adjacent first electrodes 14, and may cover an end part of the first electrode 14. The insulating film 15 may be provided to separate the first electrodes 14 provided for respective pixels from one another and to secure an insulating property between the first electrode 14 and the second electrode 17. The insulating film 15 may be made of a material such as an acrylic resin and a polyimide resin, for example.

The organic layer 16 provided between the first electrode 14 and the second electrode 17 may include the light-emitting layer made of an organic compound. The organic layer 16 may include, for each pixel, a red light-emitting layer, a green light-emitting layer, and a blue light-emitting layer, for example. In the light emitting-layer, recombination of holes and electrons injected, respectively, through the first electrode 14 and the second electrode 17 causes excitons to be generated, thus allowing for light emission. The organic layer 16 may include a hole transport layer and a hole injection layer between the light-emitting layer and the first electrode 14. The organic layer 16 may include an electron transport layer and an electron injection layer between the light-emitting layer and the second electrode 17.

The second electrode 17 faces the first electrodes 14, with the organic layer 16 being interposed therebetween. The second electrode 17 is provided in common for the pixels. The second electrode 17 may be provided throughout an entire surface of the display region 110A. The second electrode 17 may serve as an electrode that injects electrons into the light-emitting layer of the organic layer 16, for example. The second electrode 17 may be made of an electrically-conductive material having light-transmissivity, for example. The second electrode 17 may be configured by a transparent electrically-conductive film made of a material such as indium-tin oxide (ITO), indium-zinc oxide (IZO), and indium-gallium-zinc oxide (IGZO), for example.

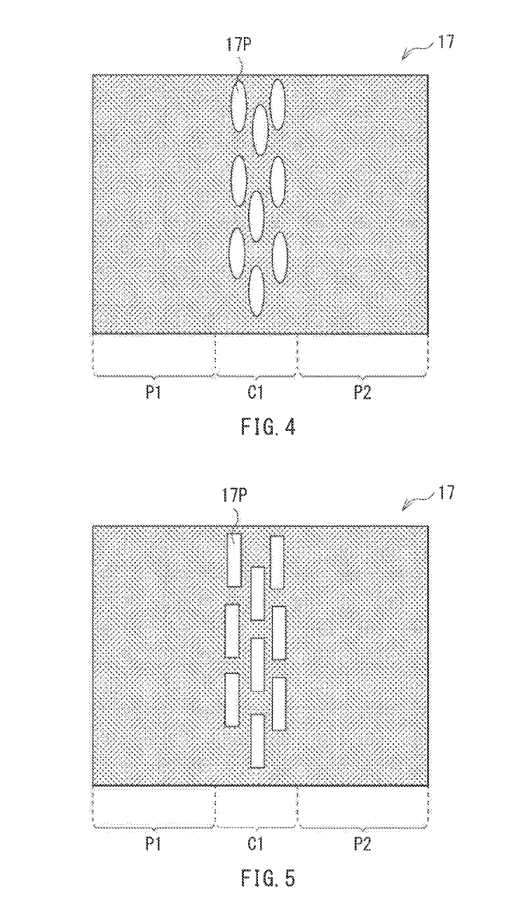

FIG. 4 illustrates a planar configuration of the second electrode 17. In the present example embodiment, the second electrode 17 has one or more openings 17P at the curved part C1, i.e., at a location that faces the curved part C1 of the substrate 11. This allows for reduction in stress to be applied to the second electrode 17, although the detail is described later.

For example, a plurality of openings 17P may be provided throughout the curved part C1 in a patterned manner. The opening 17P may be elliptical, for example. At the planar parts P1 and P2, i.e., regions corresponding to the planar parts P1 and P2 of the substrate 11, the second electrode 17 may be provided in a solid film form. In other words, the second electrode 17 may be provided throughout each of the planar parts P1 and P2, without an opening being provided.

As illustrated in FIG. 4, adjacent openings 17P may be arranged in a staggered manner. Alternatively, adjacent openings 17P may be arranged in an aligned manner, although the illustration is not given.

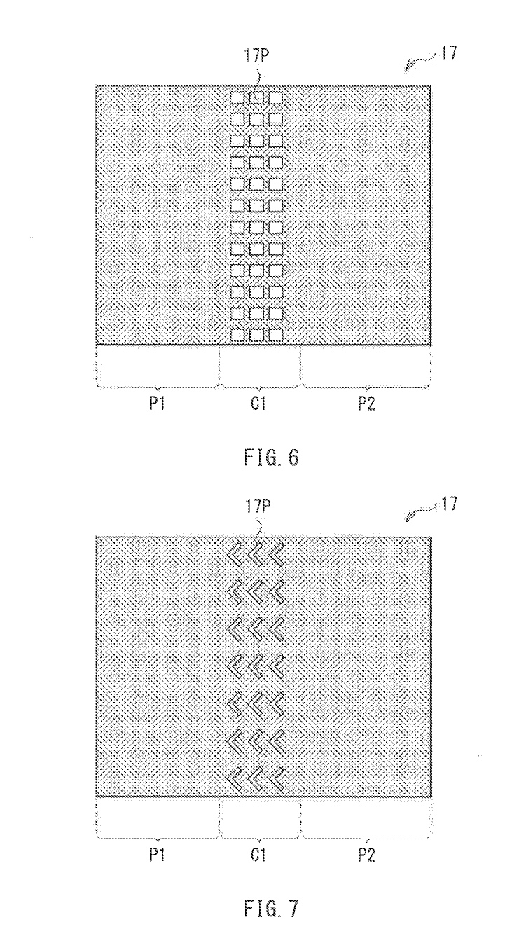

As illustrated in FIGS. 5 and 6, the opening 17P may be quadrangular. The opening 17P may have a rectangular shape as illustrated in FIG. 5. Alternatively, the opening 17P may have a square shape as illustrated in FIG. 6. Although illustration is omitted, the opening 17P may have any of various shapes such as a circle, a triangle, and a polygon having five or more angles. The plurality of openings 17P may be arranged regularly or irregularly.

As illustrated in FIG. 7, the opening 17P may be L-shaped, for example. In other words, the opening 17P may have a substantially right-angled bent shape. Although illustration is omitted, the opening 17P may have a curved shape. Although FIGS. 4 to 7 each illustrate a case where the plurality of openings 17P have the same size and shape as one another, the plurality of openings 17P may have sizes and shapes that are different from one another.

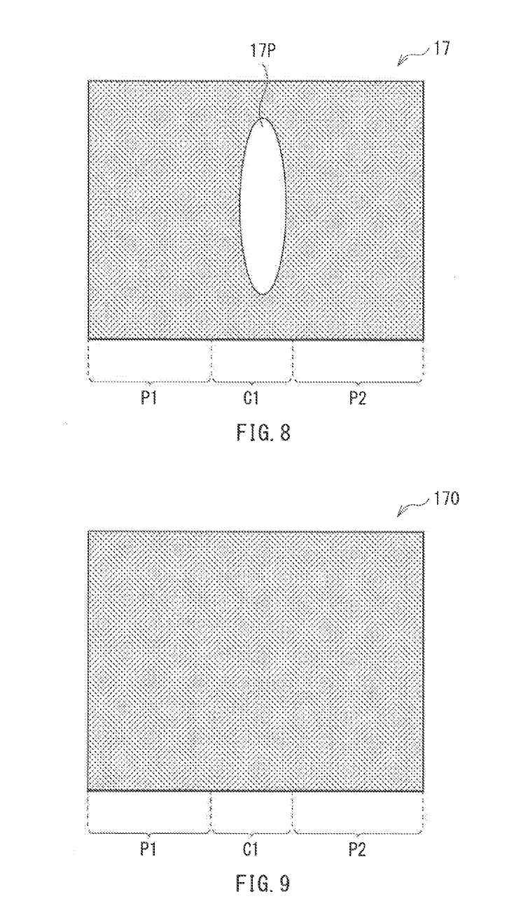

As illustrated in FIG. 8, the number of the opening 17P may be one.

The protective layer 18 that covers the second electrode 17 may contain an inorganic material such as silicon nitride and silicon oxide, for example.

### [Manufacturing Method]

The display unit 1 as described above may be manufactured, for example, as follows.

First, for example, an unillustrated support substrate made of a material such as glass may be joined onto a rear surface of the substrate 11 of the flexible substrate, for example. Next, the barrier film 12 may be formed on the entire front surface of the substrate 11 supported by the support substrate. Subsequently, the TFT layer 13 may be formed. More specifically, the semiconductor layer 131 made of any of the above-described materials (e.g., oxide semiconductor) may be first formed on the barrier film 12 by means of a sputtering method, for example. Thereafter, methods such as photolithography and etching may be used to pattern the formed semiconductor layer 131 into a predetermined shape. Subsequently, the gate insulating film 132 made of any of the above-described materials may be formed using a chemical vapor deposition (CVD) method, for example. Thereafter, the gate electrode 133 made of any of the above-described materials may be formed in a pattern on the gate insulating film 132, following which the thus-formed gate electrode 133 may be used as a mask to perform patterning of the gate insulating film 132 by means of etching of the gate insulating film 132. Thereafter, the interlayer insulating film 134A, the source-drain electrode, and the interlayer insulating film 134B may be provided, and the connection hole H1 may be formed in the interlayer insulating films 134A and 134B. This may form the TFT layer 13.

After the formation of the TFT layer 13, the first electrode 14, the insulating film 15, the organic layer 16, and the second electrode 17 may be formed in this order on the TFT layer 13. For example, a method such as mask sputtering and mask deposition may be used to form a pattern of the openings 17P in the second electrode 17. Alternatively, it is also possible to form a desired pattern of the openings 17P by a method such as etching after formation of the transparent electrically-conductive film, for example, on the entire surface. Finally, the protective layer 18 may be formed on the second electrode 17, and thereafter the support substrate may be detached from the substrate 11. This may complete the display unit 1 illustrated in FIG. 3.

### [Workings and Effects]

In the display unit 1 according to the present example embodiment, each pixel of the display region 110A may be driven to perform display on the basis of an image signal to be inputted from the outside, thus allowing an image to be displayed. More specifically, when a drive current is injected into each pixel through the first electrode 14 and the second electrode 17, the recombination of holes and electrons causes excitons to be generated, thus allowing for light emission in the organic layer 16, i.e., in the light-emitting layer. This may cause red light, green light, and blue light, for example, to be emitted from each pixel. These pieces of light may be extracted through the protective layer 18, thus allowing for image display. The display unit 1 is bendable, and is able to be folded and opened by freely varying the curvature of the curved part C1.

In the present example embodiment, even when the curvature of the curved part C1 is increased, stress to be applied to the second electrode 17 is reduced, owing to the openings 17P that are provided in the second electrode 17 of the curved part C1. Description is given below of this reduction in stress to be applied to the second electrode 17, using a comparative example.

FIG. 9 illustrates a planar configuration of a second electrode, i.e., a second electrode 170 according to a comparative example. In this second electrode 170, the curved part C1 also has a configuration similar to those of the planar parts P1 and P2. In other words, the second electrode 170 is not provided with openings in the curved part C1, either, thus allowing the second electrode 170 to have the solid film form throughout the planar parts P1 and P2 and the curved part C1. Use of such a second electrode 170 in the bendable display unit causes extremely large stress to be applied to the second electrode 170 of the curved part C1 when the curvature of the curved part C1 is increased. This may result in damage of the second electrode 170. In particular, the second electrode 170 configured by the transparent electrically-conductive film has low critical fracture stress, and is more likely to be damaged than other parts.

In contrast, the second electrode 17 of the present example embodiment is provided with the openings 17P at the curved part C1. Thus, a portion of the stress to be applied to the second electrode 17 upon the increase in the curvature of the curved part C1 passes through the second electrode 17 via the openings 17P, without affecting the second electrode 17. In other words, the portion of the stress to be applied to the second electrode 17 is relieved via the openings 17P. In this manner, the stress to be applied to the second electrode 17 is reduced in the display unit 1, thus making it possible to prevent the damage of the second electrode 17 caused by the increase in the curvature of the curved part C1.

Moreover, the second electrode 17 has the openings 17P only at the curved part C1, but the planar parts P1 and P2 are not provided with the openings. In other words, the second electrode 17 is provided throughout the planar parts P1 and P2. This makes it possible to suppress increase in resistance of the second electrode 17 as compared with a case where the planar parts P1 and P2 are also provided with the openings.

As has been described hereinabove, the openings 17P are provided in the second electrode 17 of the curved part C1. This reduces the stress to be applied to the second electrode 17. Thus, it becomes possible to reduce load to be applied to the curved part C1. Further, the second electrode 17 may be provided throughout the planar parts P1 and P2. This makes it possible to suppress the increase in the resistance of the second electrode 17.

### [Functional Configuration Example]

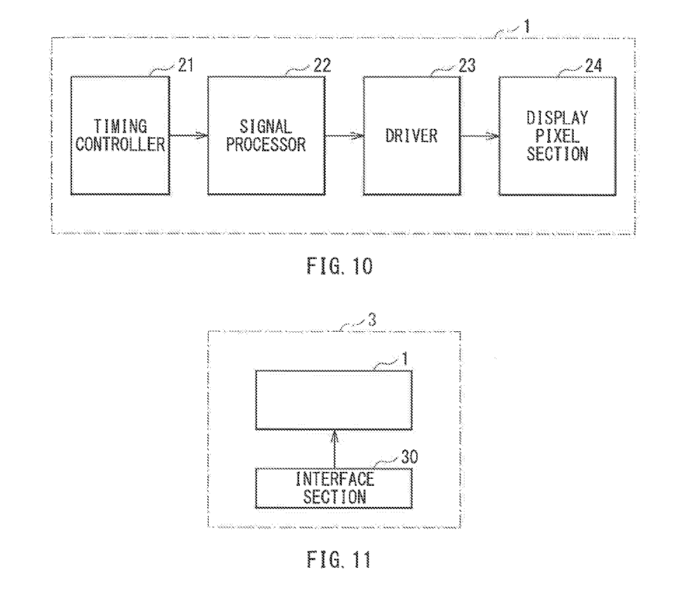

FIG. 10 illustrates a functional block configuration of the display unit 1 described in the foregoing example embodiment.

The display unit 1 may display, as an image, an image signal inputted from the outside or generated inside the display unit 1. The display unit 1 may include, for example, a timing controller 21, a signal processor 22, a driver 23, and a display pixel section 24.

The timing controller 21 may include a timing generator that generates various timing signals, i.e., control signals. The timing controller 21 may control driving of the signal processor 22, for example, on the basis of the various timing signals. The signal processor 22 may perform a predetermined correction on, for example, the digital image signal inputted from the outside, and may output the thus-obtained image signal to the driver 23. The driver 23 may include circuits such as a scanning line drive circuit and a signal line drive circuit, for example. The driver 23 may drive each pixel of the display pixel section 24 through various control lines. The display pixel section 24 may include, for example, a display device such as an organic EL device and a pixel circuit that drives the display device on a pixel basis. The thin-film transistor of the TFT layer 13 may be used, for example, for various circuits constituting a portion of the driver 23 or a portion of the display pixel section 24, among the above-described circuits.

### [Examples of Electronic Apparatus]

The display unit 1 described in the foregoing example embodiment may be used for various types of electronic apparatuses. FIG. 11 illustrates a functional block configuration of an electronic apparatus 3. Non-limiting examples of the electronic apparatus 3 may include a television, a personal computer (PC), a smartphone, a tablet PC, a mobile phone, a digital still camera, and a digital video camera.

The electronic apparatus 3 may include, for example, the above-described display unit 1 and an interface section 30. The interface section 30 may be an input section that receives various signals, a power supply, for example, from the outside. The interface section 30 may include a user interface such as a touch panel, a keyboard, and operation buttons, for example.

Although description has been given hereinabove with reference to the example embodiment, the technology is not limited thereto, but may be modified in a wide variety of ways. For example, factors such as a material and a thickness of each layer exemplified in the foregoing example embodiment are illustrative and non-limiting. Any other material, any other thickness, and any other factor may be adopted besides those described above.

Although description has been given, in the foregoing example embodiment, of the case where the top gate thin-film transistor is adopted for the TFT layer 13, a bottom gate thin-film transistor may also be adopted for the TFT layer 13.

Moreover, although description has been given, in the foregoing example embodiment, of the case where the top emission display unit is adopted as the display unit 1, a bottom emission display unit may also be adopted as the display unit 1.

The effects described in the foregoing example embodiment, etc. are mere examples. The effects according to an embodiment of the disclosure may be other effects, or may further include other effects in addition to the effects described hereinabove.

It is to be noted that the technology may also have the following configurations.

(1)

A display unit including:

a substrate provided with a display region that includes a plurality of pixels, the substrate having a curved part and a planar part in the display region;

a first electrode provided over the substrate in the display region;

a second electrode that faces the first electrode and is provided in common for the plurality of pixels, the second electrode having one or more openings at a location that faces the curved part; and

an organic layer provided between the first electrode and the second electrode.

(2)

The display unit according to (1), in which

the one or more openings include a plurality of openings, and

the second electrode has the plurality of openings.

(3)

The display unit according to (1) or (2), in which the second electrode is provided throughout a location that faces the planar part.

(4)

The display unit according to any one of (1) to (3), in which the second electrode is configured by a transparent electrically-conductive film.

(5)

The display unit according to any one of (1) to (4), in which the one or more openings are each elliptical.

(6)

The display unit according to any one of (1) to (4), in which the one or more openings are each quadrangular.

(7)

The display unit according to any one of (1) to (4), in which the one or more openings are each L-shaped.

(8)

The display unit according to any one of (1) to (7), further including a TFT layer provided between the substrate and the first electrode.

(9)

The display unit according to any one of (1) to (8), in which the substrate includes a flexible substrate.

(10)

An electronic apparatus provided with a display unit, the display unit including:

a substrate provided with a display region that includes a plurality of pixels, the substrate having a curved part and a planar part in the display region;

a first electrode provided over the substrate in the display region;

a second electrode that faces the first electrode and is provided in common for the plurality of pixels, the second electrode having one or more openings at a location that faces the curved part; and

an organic layer provided between the first electrode and the second electrode.

In the display unit and the electronic apparatus according to respective embodiments of the technology, the second electrode of the curved part is provided with the openings, thus causing a portion of force to be applied to the second electrode to pass through the second electrode via the openings without affecting the second electrode.

In the display unit and the electronic apparatus according to the respective embodiments of the technology, the second electrode of the curved part is provided with the openings, thus making it possible to reduce stress to be applied to the second electrode. Hence, it becomes possible to reduce load to be applied to the curved part. It is to be noted that the effects described herein are not necessarily limitative, and may be any effects described in the disclosure.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” as used herein can allow for a degree of variability in a value or range. Moreover, no element or component in this disclosure is intended to be dedicated to the public regardless of whether the element or component is explicitly recited in the following claims.

What is claimed is:

1. A display unit comprising:
a substrate provided with a display region that includes a plurality of pixels, the substrate having a curved part and a planar part in the display region;
a first electrode provided over the substrate in the display region;
a second electrode that faces the first electrode and is provided in common for the plurality of pixels, the second electrode having one or more openings at a location that faces the curved part; and
an organic layer provided between the first electrode and the second electrode.

2. The display unit according to claim 1, wherein
the one or more openings comprise a plurality of openings, and
the second electrode has the plurality of openings.

3. The display unit according to claim 1, wherein the second electrode is provided throughout a location that faces the planar part.

4. The display unit according to claim 1, wherein the second electrode is configured by a transparent electrically-conductive film.

5. The display unit according to claim 1, wherein the one or more openings are each elliptical.

6. The display unit according to claim 1, wherein the one or more openings are each quadrangular.

7. The display unit according to claim 1, wherein the one or more openings are each L-shaped.

8. The display unit according to claim 1, further comprising a TFT layer provided between the substrate and the first electrode.

9. The display unit according to claim 1, wherein the substrate comprises a flexible substrate.

10. An electronic apparatus provided with a display unit, the display unit comprising:
a substrate provided with a display region that includes a plurality of pixels, the substrate having a curved part and a planar part in the display region;
a first electrode provided over the substrate in the display region;
a second electrode that faces the first electrode and is provided in common for the plurality of pixels, the second electrode having one or more openings at a location that faces the curved part; and
an organic layer provided between the first electrode and the second electrode.
